(19) United States
(12) Patent Application Publication
(10) Pub. No.: US 2006/0276023 A1
(43) Pub. Date: Dec. 7, 2006

(54) METHOD FOR FORMING BUMPS

(76) Inventors: Min-Lung Huang, Kao-Hsiung City (TW); Tsung-Hua Wu, Kao-Hsiung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/420,802

(22) Filed: May 29, 2006

(30) Foreign Application Priority Data
Jun. 3, 2005 (TW) 094118352

(51) Int. Cl. H01L 21/44

(52) U.S. Cl. 438/612

(57) ABSTRACT

A method for forming bumps is disclosed. First, a substrate having an under bump metallurgy (UBM) layer thereon is provided. Next, a patterned photoresist is disposed over the surface of the UBM layer, in which an opening is formed within the photoresist to expose part of the UBM layer. Next, a foot plating is disposed into the opening to partially cover the UBM layer and a solder is deposited into the opening thereafter. After removing the photoresist, an etching process is performed to remove part of the foot plating and the UBM layer by utilizing the solder as a mask. A reflow process is performed thereafter to transform the solder into a bump.

### BACKGROUND OF THE INVENTION

1. Field of the Invention

The present invention relates to a method for forming bumps.

2. Description of the Prior Art

Flip-chip packaging processes are one of the most popular electronic packaging processes utilized today. In contrast to the some other packaging processes, the dies utilized in flip-chip packaging are not electrically connected to a packaging substrate via a bonding pad through a wire bonding process. Instead, the bonding pads are inverted and solder bumps are utilized to electrically connect and mount the dies onto the packaging substrate. Ideally, flip-chip packaging processes are able to significantly reduce the size of package structures and increase the circuit transmission between the dies and the packaging substrate because no extra wires are required for establishing a connection.

Please refer to FIG. 1 through FIG. 6. FIG. 1 through FIG. 6 are perspective diagrams showing the means of fabricating bumps 10 according to the prior art. As shown in FIG. 1, a substrate 12, such as a wafer having completed internal devices and wirings, is first provided. Next, a patterned passivation layer 14 is disposed on the surface of the substrate 12 to expose a plurality of solder pads 16. Preferably, the solder pads 16 are composed of copper or aluminum and utilized to electrically connect the internal wires (not shown) within the substrate 12 and the external wires (not shown) located above the packaging substrate.

Next, as shown in FIG. 2, a series of sputtering, deposition, and etching process are performed to form an under bump metallurgy layer 18 on each of the solder pads 16 and the passivation layer 14. The under bump metallurgy layer 18 is composed of aluminum, nickel vanadium, and copper or titanium, nickel vanadium, and copper. As shown in FIG. 3, a photoresist 20 is formed on the substrate 12 and covering the passivation layer 14. Preferably, the photoresist 20 is composed of a dry film photoresist or a liquid type photoresist.

As shown in FIG. 4, an exposure process and a development process are performed to pattern the photoresist 20 and form a plurality of openings 22 within the photoresist 20, in which the openings 22 expose the under bump metallurgy layer 18 above each of the solder pads 16. Next, as shown in FIG. 5, an electroplating process is performed to deposit a solder 24 composed of tin or copper in each of the openings 22, and the photoresist 20 is stripped thereafter. As shown in FIG. 6, a reflow process is performed to form a plurality of bumps 10 on the corresponding solder pads 16, thus completing the conventional method for fabricating the bumps 10.

However, when the openings 22 are formed within the photoresist 20, developers and other chemicals utilized during the exposure and development process will corrode the photoresist 20 connecting the under bump metallurgy layer 18 and result in an undercut phenomenon, thereby producing a plurality of undercut holes 26 with different sizes. As a result, the solder 24 deposited in the openings 22 later in the process will cover the under bump metallurgy layer 18 exposed from the openings 22 and also fill the undercut holes 26. After the reflow process is performed, the bottom area of the bumps 10 will enlarge significantly and become uneven due to the solder 26 filled within the undercut holes 26, thereby influencing the yield and stability of the entire fabrication process. Hence, it has become an important task to determine how to effectively control the size of the bumps during the reflow process.

### SUMMARY OF THE INVENTION

It is therefore an objective of the claimed invention to provide a method for forming bumps for solving the above-mentioned problems.

According to the claimed invention, a method for forming bumps includes the following steps: providing a substrate having an under bump metallurgy (UBM) layer formed thereon; forming a patterned photoresist on a surface of the under bump metallurgy layer, wherein the patterned photoresist comprises at least one opening for exposing a portion of the under bump metallurgy layer; forming a foot plating in the opening to partially cover the surface of the under bump metallurgy layer; disposing a solder in the opening; performing a stripping process to remove the patterned photoresist; performing an etching process by utilizing the solder as a mask to remove a portion of the foot plating and a portion of the under bump metallurgy layer; and performing a reflow process to form a bump.

By forming a patterned photoresist on the surface of an under bump metallurgy layer, in which the patterned photoresist includes an opening that exposes a portion of the under bump metallurgy layer, forming a foot plating in the opening and covering the exposed under bump metallurgy layer and the undercut holes, and depositing a solder in the opening and removing a portion of the foot plating and the under bump metallurgy layer not covered by the solder, the claimed invention is able to improve the stability and yield of the overall fabrication process by effectively controlling the size of the bumps formed during the reflow process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 6 are perspective diagrams showing the means of fabricating a bump according to the prior art.

FIG. 7 through FIG. 12 are perspective diagrams showing the means of fabricating a bump according to a preferred embodiment of the present invention.

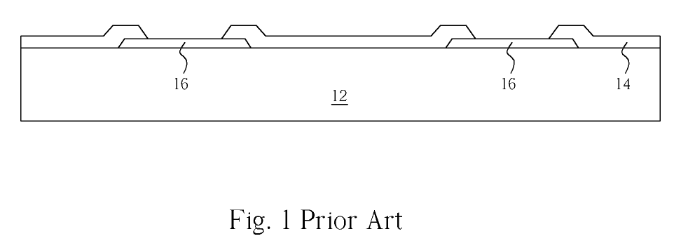

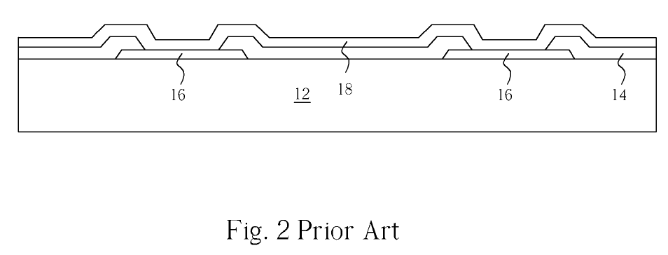

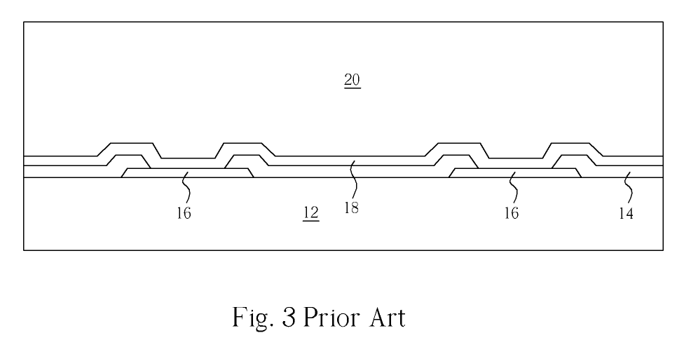

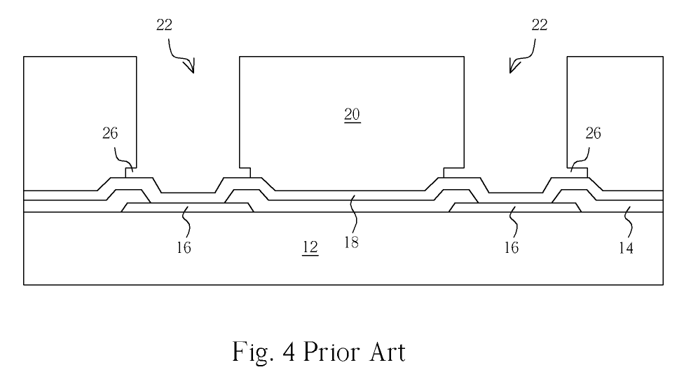

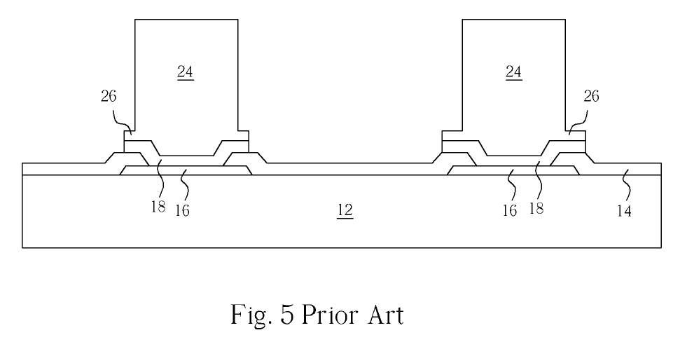

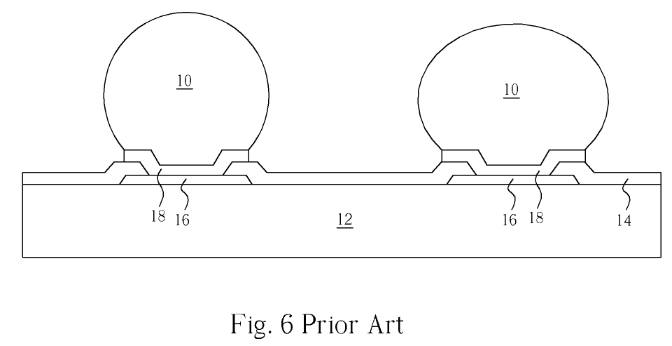

### DETAILED DESCRIPTION

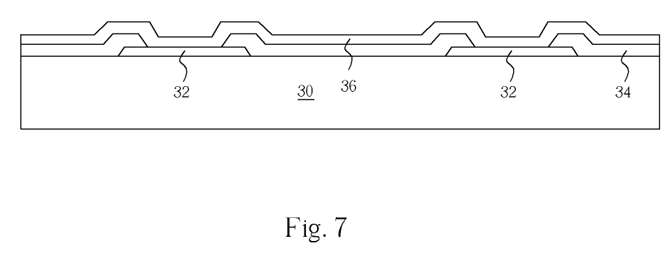

Please refer to FIG. 7 through FIG. 12. FIG. 7 through FIG. 12 are perspective diagrams showing the means of fabricating a bump according to the preferred embodiment of the present invention. As shown in FIG. 7, a substrate 30, such as a wafer is provided. The surface of the substrate 30 includes a plurality of conductive structures, such as a plurality of solder pads 32. Composed of copper or aluminum, the solder pads 32 are utilized to electrically connect the internal wires (not shown) within the substrate 30 and the external wires (not shown) located on the packaging substrate. Next, a patterned passivation layer 34 is formed on the surface of the substrate 30 to partially expose the surface of the solder pads 32 and protect the internal wires (not shown). Next, a sputtering, deposition, and etching process are performed to form an under bump metallurgy layer 36 on the surface of the exposed solder pads 32 and the patterned passivation layer 34. The under bump metallurgy layer 36 is composed of an adhesion layer, a barrier layer, and a wetting layer. The adhesion layer provides an adhesive property to the solder pads 32 and the patterned passivation layer 34, in which the adhesion layer is composed of aluminum, titanium, chromium, or titanium tungsten. The barrier layer prevents the diffusion of metal between the bump and the solder pad, in which the barrier layer is composed of nickel vanadium or nickel. The wetting layer enhances the attaching ability between the under bump metallurgy layer 36 and the bump, in which the wetting layer is composed of copper, molybdenum, or platinum.

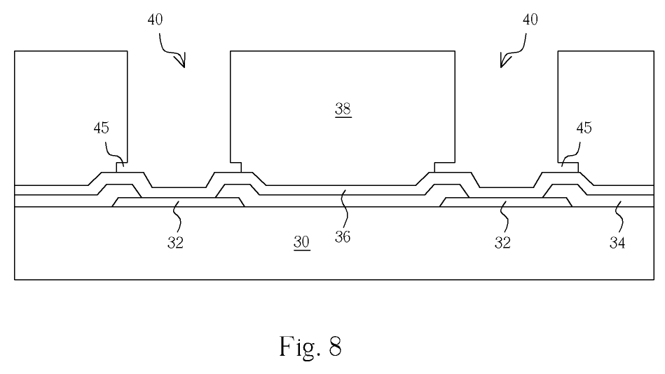

Next, as shown in FIG. 8, a patterned mask, such as a photoresist 38 is formed on the under bump metallurgy layer 36. Preferably, the photoresist 38 is composed of a dry film photoresist or a liquid type photoresist. An exposure and development process is performed thereafter to expose the under bump metallurgy layer 36 above each of the solder pads 32 and form a plurality of openings 40. The openings 40 are utilized as a bonding area for the under bump metallurgy layer 36 and the solder deposited in the later process, in which the depth of the openings 40 is directly related to the height of the bumps formed afterwards. According to the preferred embodiment of the present invention, the openings 40 are located directly above the solder pads 32. Alternatively, depending on the design and demand of the fabrication, a repeat distribution layer (RDL) process can be performed to form the openings 40 adjacent to the solder pads 32 and above the under bump metallurgy layer 36.

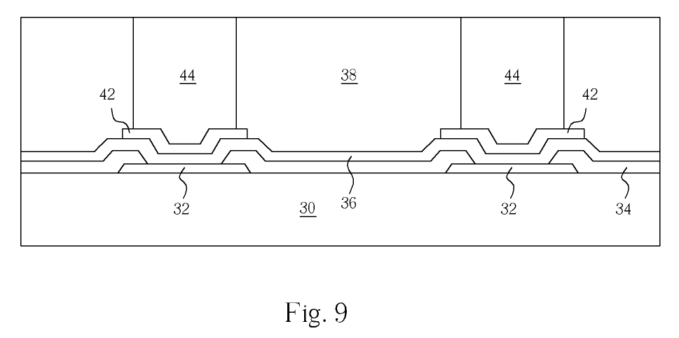

Next, a foot plating 42 composed of copper is formed on the surface of the under bump metallurgy layer 36 within each of the openings 40. As shown in FIG. 9, the foot plating 42 is formed in the bottom of the openings 40 and covering the exposed under bump metallurgy layer 36. After forming the foot plating 42, an electroplating process is performed to deposit a solder 44 within the openings 40 and completely covering the foot plating 42.

Unfortunately, developers and other chemicals utilized in the exposure and development process often corrode some of the bottom portion of the photoresist 38 connecting the under bump metallurgy layer 36 during the formation of the openings 40 and result in an undercut phenomenon, thereby producing a plurality of undercut holes 45 with different sizes. In order to solve this problem, the present invention first forms a foot plating 42 in the bottom of the openings 40 to fill the undercut holes 45 located on the bottom of the photoresist 38, and then performs an electroplating process to deposit a solder 44 in the openings 40 and covering the foot plating 42 completely. By controlling the etching selectivity based on the material, thickness, and lattice structure utilized for the foot plating 42 and the solder 44, the foot plating 42 and the under bump metallurgy layer 36 not covered by the solder 44 are removed down to the surface of the passivation layer 34. As a result, the size of the solder bumps formed during the reflow process can be effectively controlled.

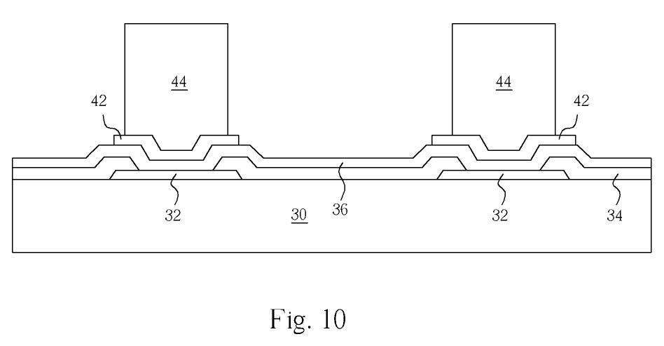

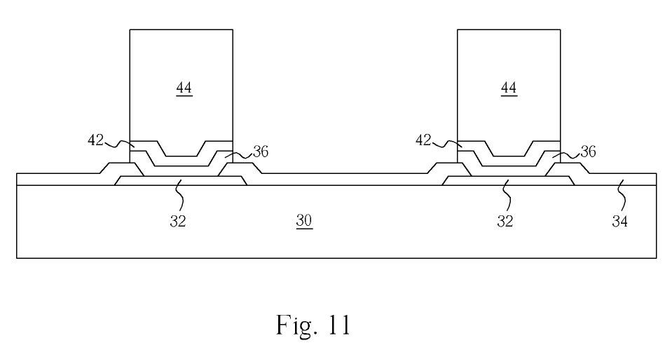

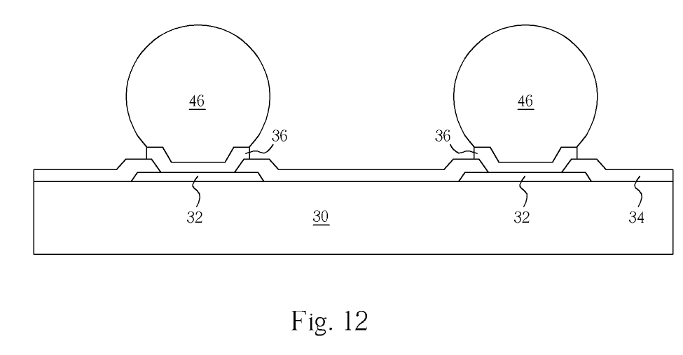

As shown in FIG. 10, a stripping process is performed to remove the photoresist 38. Next, as shown in FIG. 11, an etching process is performed by utilizing the solder 44 as a mask to etch part of the foot plating 42 and part of the under bump metallurgy layer 36, until reaching the surface of the patterned passivation layer 34. As shown in FIG. 12, a reflow process is performed thereafter to transform the solder 44 via surface tension to a ball shape, thereby forming a plurality of bumps 46 on the corresponding solder pads 32 and the under bump metallurgy layer 36.

In contrast to the conventional method of forming bumps, the present invention first forms a patterned photoresist on the surface of an under bump metallurgy layer, in which the patterned photoresist includes an opening that exposes a portion of the under bump metallurgy layer, forms a foot plating in the opening and covers the exposed under bump metallurgy layer and the undercut holes, deposits a solder in the opening and removes a portion of the foot plating and the under bump metallurgy layer not covered by the solder, thereby effectively controlling the size of the bumps formed during the reflow process and improving the stability and yield of the overall fabrication process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for forming bumps, comprising:
providing a wafer having an under bump metallurgy layer formed thereon;
forming a patterned photoresist on a surface of the under bump metallurgy layer, wherein the patterned photoresist comprises at least one opening for exposing a portion of the under bump metallurgy layer;
forming a foot plating in the opening to partially cover the surface of the under bump metallurgy layer;
depositing a solder in the opening;
performing a stripping process to remove the patterned photoresist;
performing an etching process by utilizing the solder as a mask to remove a portion of the foot plating and the portion of the under bump metallurgy layer; and
performing a reflow process to form a bump.

2. The method of claim 1 further comprising:
forming at least one solder pad between the wafer and the under bump metallurgy layer for electrically connecting the circuits within the wafers; and
forming a patterned passivation layer on the wafer, wherein the patterned photoresist exposes a portion of the solder pad.

3. The method of claim 2, wherein the opening is formed above the solder pad.

4. The method of claim 1, wherein the foot plating comprises copper.

5. The method of claim 1, wherein the under bump metallurgy layer comprises an adhesion layer, a barrier layer, and a wetting layer.

6. The method of claim 1, wherein the under bump metallurgy layer is fabricated by a sputtering process.

7. The method of claim 1, wherein the process of depositing the solder in the opening is achieved by an electroplating process.
